(19) United States
(12) Patent Application Publication
(10) Pub. No.: US 2010/0146374 A1
(43) Pub. Date: Jun. 10, 2010

(54) Wireless communications method

(76) Inventor: Josef Samuelson, Rishon Lezion (IL)

Correspondence Address: Josef Samuelson, 26 Tel Hay Street, Rishon Lezion, 75277, omitted

(21) Appl. No.: 12/704,565

(22) Filed: Feb. 12, 2010

(30) Foreign Application Priority Data
Aug. 10, 2007 (GB) 0715494.1
Sep. 20, 2007 (GB) 0718272.8
Nov. 16, 2007 (GB) 0722485.0

(51) Int. Cl. H03M 13/00; G06F 11/10; G06F 1/32; G06F 15/16

(52) U.S. Cl. 714/807; 714/E11.032; 713/323; 709/207

(57) ABSTRACT

A Wireless communications protocol/method comprises: a. Sensors data size and structure are constant, and consist of several fields; b. The sensors message include one or more of the following: 1) a 8 to 16 bits long preamble of a start sequence, for example a binary 1010 . . . binary sequence 2) a sync sequence of for example 8 bits of a 11001100 sequence 3) a sensor's unique ID number of for example 8 to 16 bits 4) several bits of sensor's internal clock counter 5) several bits indicating the message type 6) data, for example 16 bits of data, and/or 7) CRC (for Cyclic Redundancy Check purposes), for example 8 to 16 bits. A method for detecting leakage from a pipe uses multiple channels/inputs, wherein a low frequency range input measures seismic noises, and a high frequency range input measures cavitation noises.

### CROSS REFERENCE TO RELATED APPLICATIONS

The present application claims priority from the patent application No. GB0715494.1 filed by the present applicant in Great Britain on 10 Aug. 2007, the application No. GB0718272.8 filed by the present applicant in Great Britain on 20 Sep. 2007, the application No. GB0722485.0 filed by the present applicant in Great Britain on 16 Nov. 2007, and the application No. US12523534 filed by the present applicant in U.S.A. on 17 Jul. 2009, wherein US '534 is a U.S. National Stage under 35 USC 371 from PCT/IB2008/53212 filed on 11 Aug. 2008, all entitled “Monitoring system and method”.

### FIELD OF THE INVENTION

The present invention relates to a Communications protocol and method which is low power, thus economic on use of battery power.

### DESCRIPTION OF RELATED ART

There is a need for a distributed system to protect a large area or an elongated path such as a pipeline site or underground electrical power lines. There is a need to detect undesired human activities, a technical failure such as leakage from a pipe, or hazardous natural phenomena.

Acoustic and/or other types of sensors buried in the ground may be used for that purpose, however there are problems with implementing such a system—how to connect a multitude of sensors, how to process a multitude of signals from such sensors, etc.

The operation of a large scale system is difficult to monitor and manage. There may be loss of sensitivity or an unacceptable level of false alarms, or loss of data.

The sensor itself may be rendered ineffective because of ambient noise and interference, including among others magnetic fields, electrical fields and/or electromagnetic (radio frequency) waves or a misinterpretation of seismic or tectonic phenomena.

In prior art, sensors such as geophones may be sensitive to interference due to external fields, such as to electric, magnetic or electro-magnetic fields.

For a large system, wireless (i.e. radio frequency) communications are an attractive option—there is no need for laying cables, etc. Another attractive option is a fiber-optic cable. In both cases, however, there are no provisions for supplying the sensor units with electrical power.

In a system where each sensor unit uses its internal battery power, it is important to preserve battery life by using as low an energy level as possible.

In this case, it is important that the unit's power consumption be minimal, to prolong battery life. The unit communicates through wireless, therefore it is important to minimize the power consumption required to transmit data.

It may be difficult for an operator to view the status of a multitude of sensors. If the system issues an alarm for every sensor activation, this may a cause a high false alarm rate, which is highly undesirable.

Metallic structures such as oil pipes are protected against corrosion with the application of a cathodic voltage thereto. This protection is effective while it lasts, however a drop in the cathodic voltage may leave the structure defenseless. Even more destructive may be an accidental reversal of the polarity of the cathodic voltage, for example when exposed metallic parts are diluted by the current.

For a long pipeline, it may be difficult or impossible to periodically measure the cathodic voltage to ensure its presence.

### BRIEF SUMMARY OF THE INVENTION

The present disclosure relates to improvements in distributed data acquisition systems using various sensors buried in the ground, or elsewhere. The system may use acoustic sensors or geophones, among others.

A modular structure allows the system to be deployed to protect for example a designated area, a pipeline path or underground electrical power lines.

The system includes, among others, the following innovative aspects:

1. A modular, distributed system allows to protect a large area.

The system may be modified or enlarged as required. A multi-zone or multi-cellular and a multi-level processing architecture allow signals to be processed at several levels in the distributed system, to improve system's sensitivity, reduce false alarm rates and improve reliability.

A distributed monitoring and control architecture allows to monitor sensor's activations simultaneously from several locations.

The modular system architecture allows control of each individual sensor's parameters from a remote location.

A single Cell, or Zone, is a complete and independent system, that can operate even in case that other Cells or Zones are non-existent or not operative. Moreover, the same territory can be covered by several independent Cells, without any interference, thus achieving a very high level of reliability.

2. A sensor unit enclosed in a ferromagnetic shield. The casing of the whole device is a Faraday cage. Thus, the sensor and the electronic circuit are protected from external interference due to electric, magnetic or electro-magnetic fields.

The sensor itself (a geophone for example), its cables and whole electronic circuit are protected from ambient noise and electromagnetic interference, using a metallic Ferromagnetic enclosure. In the case of geophones, it is very important, because there are many strong power line induced electromagnetic fields, which may be present exactly in the reception spectrum of the very weak signals we are interested to detect.

By reducing the external electromagnetic interference over the whole spectrum, the unit can use high gain amplifiers to measure those weak signals, thus achieving a significantly improved sensitivity, without the need to filter out power lines, lightning, cosmic and other interferences, or reducing the need for such filtering.

3. The casing of a sensor unit has a directional aperture, structure or sail: the enclosure is flat, like a plate, to achieve improved impedance matching to the ground, in the energy detection axis. The sensor means within the unit is aligned with the casing, that is the sensor's directionality coincides with the directional aperture of the whole unit. This novel solution can improve the sensitivity of the sensor, especially in non stable and changing soils.

4. Integrated, sealed, shielded, corrosion protected, stand alone unit. This unit is built with a single sensor or a plurality of various sensors, including all the necessary electronic circuitry, digital processor, memory, receiver, transmitter, supervisory and energy saving subsystems, combined with a battery in a self powered, long life unit. In one embodiment, more than 12 years of operation may be achieved.

Sensors re-transmitter unit and local Cell/base station unit may have this structure.

5. Using measurements of the cathodic voltage changes to detect offenders to, or to protect from faults in, oil, gas or other pipes. The system allows quick detection of unauthorized access to oil, gas or other pipes, by monitoring the protective cathodic voltage and detecting quick changes in the voltage, due to insulation damage and as a result of ground potential change.

The new sensor unit further includes means for measuring the local cathodic voltage on a pipeline, for example. Thus, periodic measurements of this so important variable can be performed automatically. The results can be processed in the system, together with the other sensors data.

Furthermore, attack on, or damage to, high voltage underground cables can be detected by measuring the electrical fields in the ground near the cables, possibly together with acoustic noises.

6. A Sophisticated algorithm for processing sensors data in a four dimensional space including location and time. Each sensor's location is known in the system. Each activation of each sensor is stored together with a physical location 2 time stamp, message type and data. The information is advantageously processed in a 4D space, to reliably detect intrusions into the protected area or volume.

The algorithm checks events history and sequence in a 3D space, analyzes their nature, computes the route of event progress, automatically calculates detection thresholds and average background noise levels.

This unique constant 4D analysis quickly discovers any anomalies, and allows to protect wide areas against intruders and offenders, as well as to detect gas leakage or liquid spills from high pressure long pipes.

7. Detect leakage from pipe using multiple channels/inputs. Multi-frequency sensor unit, using various physical phenomena detection, reduces false alarms, while providing reliable detection of liquid leakage from the pipe. This innovative approach, based on detection of simultaneous events from a different nature, significantly reduces the need for complicated signal processing. The use of this technique allows precise and quick event identification, using a small, low cost sensor unit having a lower power consumption.

8. Communication protocol, low power—economic on use of battery power. Initial processing at the individual sensor level helps reduce the volume of communications going to higher levels. The general communication structure is synchronous, wherein each sensor has its own session time slot, but the protocol allows the sensor to remain connected even with no transmission, in case that no event happened. Two way efficient communication realized using precise “turn on” schedule.

Message reception by a sensor from a higher level occurs immediately after a sensor's scheduled transmission. In other words, there is no need for constant sensors receiver consumption. This is a major improvement, because the sensor stays in a shut down state, more than 99% of the time. The only “must” transmission, is periodical “keep alive” short message, thus the overall energy spent on the RF link may be reduced even to less than 1% of the usual values.

A cellular structure of the system allows a second level of data processing at the cell base unit, its purpose to filter out is important to the Cell level, but irrelevant to the next level information. This reduces the volume of transmitted data even more.

According to the present invention, efficient communication methods may be implemented, which reduce the power consumption to prolong battery life. Thus, the sensor units do not need their batteries to be replaced too often, which may otherwise present an expensive maintenance demand.

Further objects, advantages and other features of the present invention will become obvious to those skilled in the art upon reading the disclosure set forth hereinafter.

### BRIEF DESCRIPTION OF THE DRAWINGS

FIG. 1 illustrates a basic cell of the alarm system

FIG. 2 illustrates the physical deployment of a multi-cell system

FIG. 3 details the structure of a typical line of sensors

FIG. 4 details the structure of a sensor unit

FIG. 5 details the structure of another embodiment of a sensor unit

FIG. 6 details the functional block diagram of the sensor unit

FIG. 7 illustrates a display and control station using a graphic human interface

FIG. 8 illustrates a distributed system with multiple display and control stations

FIG. 9 details control paths for making changes in the system

FIG. 10 details another embodiment of the unit functional block diagram

FIG. 11 illustrates an algorithm for detecting an intruder's path in a four-dimensional (space and time) space

FIG. 12 details a flow chart of an algorithm for detecting an intruder's path in the four-dimensional space

FIG. 13 details an example of computing the precise location from the simultaneous activation of several sensors

FIG. 14 details an example of the sequential activation of a plurality of sensors

FIG. 15 illustrates an example of a graphic reporting display and log file for a walk-in intruder

FIG. 16 details an example of distance evaluation from sensor signal strength data

FIG. 17 details an example of a display of historical data for sensors activation, in both graphic and tabular form

FIG. 18 details cathodic protection of a pipe

FIG. 19 details a distributed measurement of the cathodic voltage

FIG. 20 illustrates a failure mechanism of the cathodic protection

FIG. 21 illustrates signals in a system for cathodic voltage monitoring

FIGS. 22A and 22B illustrate the use of the unit's directionality (sail) to adapt to various types of waves

FIG. 23 illustrates a wireless communications protocol

FIG. 24 details a wireless communications method at the sensor unit

FIG. 25 details a wireless communications method at the base unit

### DETAILED DESCRIPTION OF THE INVENTION

A preferred embodiment of the present invention will now be described by way of example and with reference to the accompanying drawings.

### Table of Contents—Innovative Aspects

The eight aspects as presented in the Summary are detailed below as follows:

1. A modular, distributed system allows to protect a large area 11
2. A complete sensor enclosed in a ferromagnetic shield 17
3. The casing of a sensor unit has a directional aperture, structure or sail 19
4. Integrated, sealed, stand alone complete sensor with transmitter and battery 20
5. Use of cathodic voltage changes to detect offenders to, or protection faults in, oil, gas or other pipes and underground electrical cables 22
6. A Sophisticated algorithm for processing sensors data in a four dimensions 30
7. Detect leakage from pipe using multiple channels/inputs 36
8. A low power consumption, efficient communications protocol 39

### 1. A Modular, Distributed System Allows to Protect a Large Area

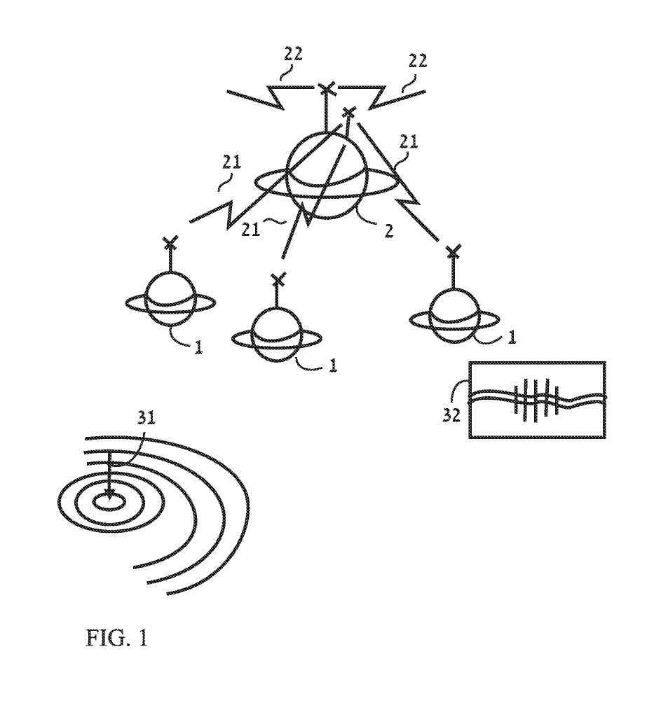

FIG. 1 illustrates a basic cell of the alarm system, including a plurality of sensor units 1. Each unit 1 may include various sensor means, signal processing and communication means.

A base unit 2, possibly with radio-frequency (RF) links, may establish communication links 21, sensor to base, and communication link 22, base to base.

The system may be modified or enlarged as required.

A multi-level processing architecture allows signals to be processed at several levels in the distributed system, to improve system's sensitivity, reduce false alarm rates and improve reliability.

For example, a geophysical event 31 may include the ground energy wave of a footstep, an animal's movement sound, a thunder. The result of the event is received in a sensor 1, as illustrated with received signal 32.

Note: Throughout the present disclosure, unless otherwise stated, it is to be understood that various types of sensors may be used, and in various combinations thereof.

Such sensors may include: geophones, microphones, hydrophones, accelerometers, magnetometers, temperature, humidity, radiation or other sensing elements. A sensor unit may include a plurality of sensors, possibly of different types.

The event 31, after being processed in the unit 1, is transmitted to the base 2. To achieve an efficient communication link, the received signals are filtered; only those complying with predefined criteria are reported to base 2. Thus, the communication channel 21 and the base 2 will not be flooded with a multitude of insignificant or irrelevant reports.

In a preferred embodiment, the unit 1 and base 2 include a sensor such as a geophone, enclosed in a ferromagnetic shield. The casing of the device protects the sensor within from interference, thus increasing the sensitivity of the device.

Furthermore, unit 1 and base 2 integrate, in a sealed unit, a stand alone geophone with a transmitter with battery in a self powered, long life unit. Thus, the system may be installed without wires between the units.

The units 1 and bases 2 preferably using a novel communication protocol, which is low power, to achieve economy in use of battery power, thus allowing the independent units to operate for prolonged time periods.

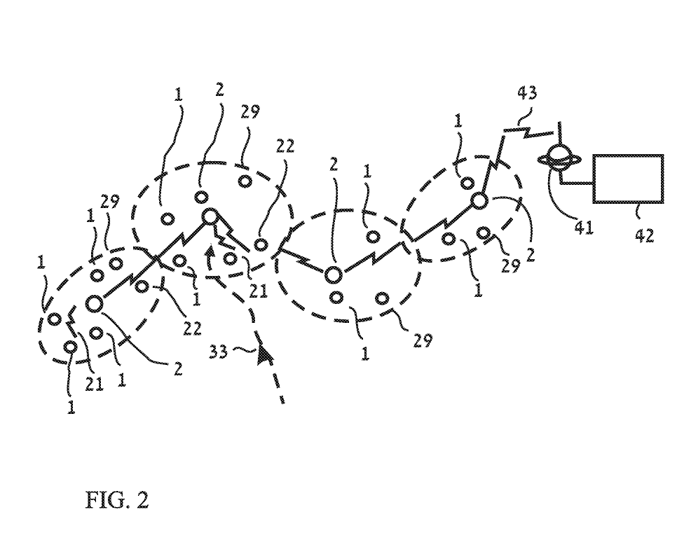

FIG. 2 illustrates the physical deployment of a multi-cell system.

Each cell 29 may include a plurality of sensor units 1, connected to a base unit 2.

The connections may be implemented, for example, using communication links 21, sensor to base. The links 21 may be implemented with wireless or wired links. Wireless may include radio or laser beams for example. Wired links may include copper wire or fiber-optic cables. The system may also include communication links 22, base to base.

Thus, a plurality of adjacent cells 29 may be connected to each other, with one or more being eventually connected to a higher level, level 3 analysis computer (LC) 42. The computer 42 may be further connected to the system using a higher level RF link 43 through a gateway 41.

The computer 42, by processing sensor's activation reports, stores all the received data and may compute a possible intruder's path 33. When such a path is detected, an alarm may be issued and the path may be reported to an operator (or to several operators).

The computer uses an advanced, sophisticated algorithm to analyse the whole picture of an event, or of a plurality of events.

### Method of Operation of the System

Level 1—the basic sensor 1. Each sensor may include a microphone, a geophone, hydrophone, accelerometer and/or other sensors, or a combination thereof.

Decision means are activated when a signal is received, to reach a decision whether to send a report to a higher level, Level 2.

A sensor 1 may send reports to its base 2, or to another base with which a communication link can be established.

Level 2—base station 2. Each base station receives signals from a plurality of sensors 1. Logic means at Level 2 can perform computations, or may compare signal levels to decide whether to send a report in a preassigned time slot. If the decision is positive, it sends pack to a base higher in the chain, such as one closer to a gateway 41 or computer. The base 2 identifies the sender of each report, which may be a specific sensor unit 1 or another base 2.

The other base will not further filter the information received from another base, but will pass it along as is. Of course, each base will filter its own sensors data, and send them to the logic computer.

It may take some time to transfer sensors reports, from base to base, toward a gateway. The time required may be of the order of several seconds to minutes, depending on the location of sensors, bases and gateway processor in the system, and the systems required response speed.

In a preferred embodiment, the system implements a distributed processing, with each base performing some computing then may pass a report along. The decision whether to send a report or not is performed according to predefined rules, such as spectral energy distribution, peak and average level of signals, the amount of simultaneous and adjacent events, long period average signal level and others.

Optionally, the system can send all the data to the processor, but it will consume more battery energy. This “transparent data mode” is used by the operator in cases when precise identification of an event, or remote sensor tune-up is needed.

A typical segment to be protected may contain, for example 16 bases or dozens of bases, connected to possibly thousands of sensors.

It is important to perform some of the data analysis in the sensor unit and at the base, so as not to overload the network, thus, only relevant data will be reported.

If there is no new, relevant data, then the sensor unit will send only a “keep alive” signal, from time to time.

The base will report only relevant activities, not the “keep alive” signals. If, however, a sensor fails to send the “keep alive” signals within a predefined time, this generates an exception signal, a sensor failure event to be reported further up the chain. Actually, the failure may relate to the sensor or its communication link. The report may also include the battery status of the sensor.

Level 3—The gateway 41 may control several cells and/or bases.

If a base sends a OK signal—then all sensors are OK.

If no exceptions are reported, then all is OK. Thus the gateway acts as a multicell controller and communication scheduler.

The gateway 41 sends the data to an algorithmic logic unit (ALU).

**End of method**

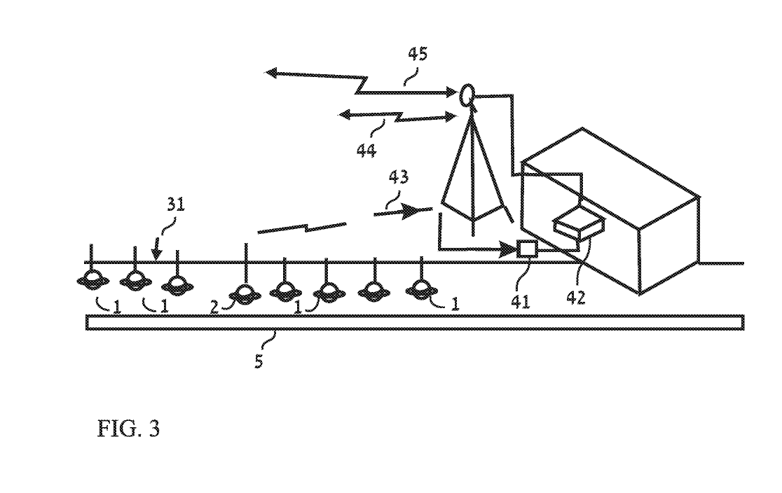

FIG. 3 details the structure of a typical line of sensors 1, to protect a pipeline 5 or underground high voltage cables, for example.

A plurality of sensor units 1 may be placed along the pipeline, with a base unit 2 connected to each group of sensors 1.

To illustrate the method of operation of the system, for example an acoustic event or disturbance 31 may activate one or several sensor units 1 in the neighborhood of that event. The number of activated sensors may depend on the amplitude of the disturbance, for example a small animal may activate one sensor, human activity may activate one to a few sensors, thunder or seismic activity may activate many sensors simultaneously.

Reports of the event from the activated sensors 1 are transferred to a base 2, where the signals reports are further processed.

If deemed adequate, a report is sent to the gateway 41 through the higher level RF or wired link 43.

From gateway 41, sensor activation reports are transferred for further processing in a level 3 analysis computer 42.

Results may be transmitted or reported to a center to be displayed to an operator, for example through a radio datalink 44 and/or Wimax link 45.

### Method of Operation of an Analytical Controller

1) It receives information from the network, through radio links and/or wired links or optical links.

The optical links may include fiber or laser or led.

2) It stores and analyzes the data.

3) It sends processed data, results and/or conclusions to an operator station with security guards, through Ethernet links 46 and/or other communication means. This achieves a real time update of the display to operator.

**End of method**

Alternately, the system may display a history of past events, not in real time. The analytical controller 48 may keep the information in memory unit 482.

In locations where there is no network available, data from base units or other data gathering units in the area may be downloaded to a hard disk, CD, DVD, diskette or flash memory, to be taken to a processing center for subsequent processing—not in real time.

The controller may be connected to other locations through an RS-232, wireless, optical network or other links 47.

In a typical embodiment, each controller may span a large sector, tens of km square of a distributed network.

### 2. A Sensor Unit Enclosed in a Ferromagnetic Shield

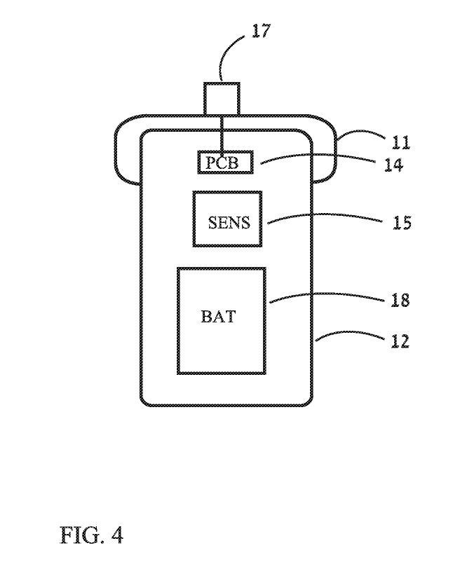

FIG. 4 details the structure of a preferred embodiment of a sensor unit 1 or base station 2. The sensor unit 1 includes an upper part (cover) casing 11, made of a Ferro-magnetic metal, and a lower part (body) casing 12, also made of a Ferro-magnetic metal.

This structure protects the sensor means 15 from ambient noise and interference, either magnetic or electrostatic or electromagnetic (radio waves).

Ambient noise is a factor limiting the performance of prior art sensors, also causing false alarms. By reducing the power level of this noise inside the sensor unit casing, the unit's sensitivity may be considerably improved.

Reports of detected events may be transmitted through an antenna and/or through a wired network via connector 17.

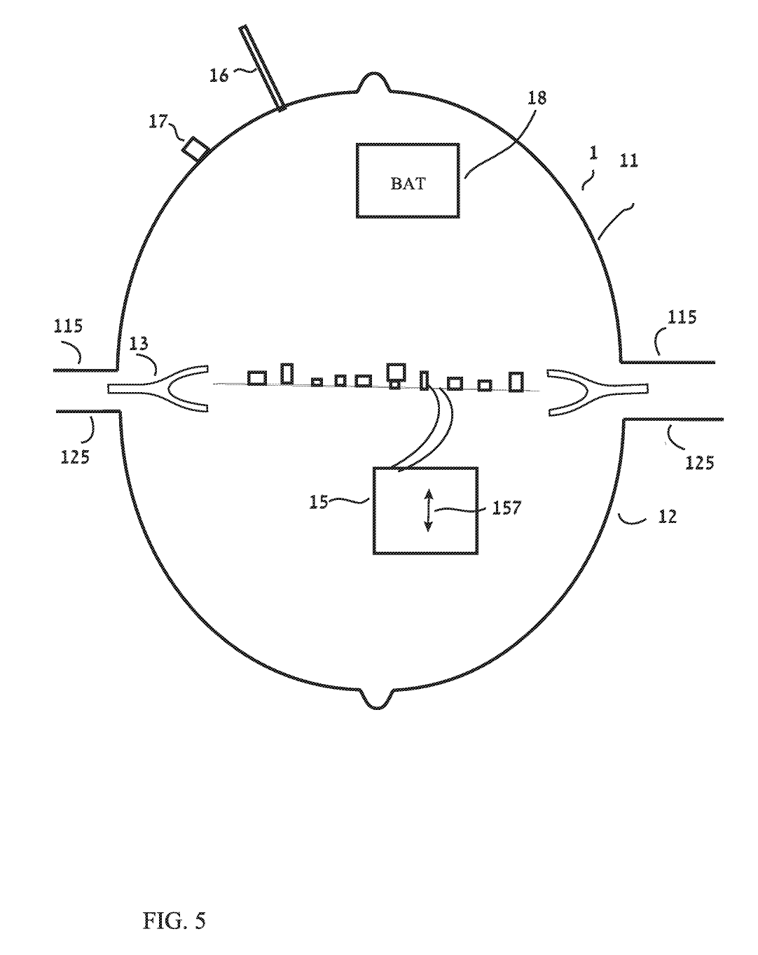

FIG. 5 details another preferred embodiment of the structure of sensor unit 1 or base 2. The sensor unit 1 includes an upper half casing 11, made of a Ferro-magnetic metal, and a lower half casing 12, also made of a Ferro-magnetic metal. This structure protects the sensor means 15 from ambient noise and interference, either magnetic or electrostatic or electromagnetic (radio waves). Ambient noise is a factor limiting the performance of prior art sensors, also causing false alarms.

A sealing ring 13 may have a dual use, also to hold the electronics board 14. Signals from the sensor 15, are processed in the electronics board 14. Reports of detected events may be transmitted through the antenna 16, and/or through a wired network via connector 17.

The casing of the device is a Faraday cage. Thus, the sensor such as a geophone is protected from external interference due to electric, magnetic or electro-magnetic fields. The use of ferromagnetic shield sealed enclosure that stores a sensor like a geophone, prevents from electro magnetic fields and power lines especially, from entering and interfering with very weak signals that generated by the sensor.

This enclosure significantly improves the signal to noise ratio of the geophone in its frequency working range.

Preferably the shielding should be effective at least in the 10-100 Hz frequency range.

The sensor unit may include various types of sensors.

A preferred sensor is a geophone, or a geophones array.

It is important that not only the sensor itself, but also its electronics be mounted within the ferromagnetic shielding.

In one embodiment, the shielding is especially effective in a 0.1-300 Hz frequency range.

In another embodiment, the shielding is especially effective in a 10-100 Hz frequency range.

In another embodiment, the shielding is especially effective in a 10 Hz-10 GHz frequency range.

The sensor means may comprise a geophone and the shielding should especially effective in the geophone's detection range. Where a geophones array is used, the shielding should be effective within the detection range of the geophone array.

### 3. The Casing of a Sensor Unit has a Directional Aperture, Structure or Sail

The enclosure of unit 1 in FIG. 5 (or base station 2, see FIG. 1) is flat, like a plate as illustrated, to achieve improved impedance matching to the ground. The sensor means within the unit is aligned with the casing, that is the sensor's directionality coincides with the directional aperture of the whole unit.

This casing has a directional aperture or sail with parts 115, 125. This structure presents a larger area for seismic waves propagating in a vertical direction. The sensor 15 inside the casing is aligned with the above aperture, having a maximal sensitivity in the direction illustrated 157. Thus, as seismic waves impinge upon the sensor unit in a direction normal to the rings 115, 125 forming the “sail”, a larger portion of the waves' power penetrates the sensor casing, and the sensor 15 itself is aligned to make best use of these waves, for example for vertical waves (S-waves) which are the main waves generated by human activity. The sensor will detect activity in a vertical axis. The sensor body acts as a sail. This structure enhances the signal strength by about 3-6 dB, according to ground type.

Within the case, the geophone sensor itself is mounted in the same direction (detection axis) to achieve maximal sensitivity in the direction of the sail, the large aperture in the case.

The sail effect can be used in any dimension—if we want also directivity in a horizontal direction, then one should mount it horizontally, with an appropriate sensor with the same orientation.

Other casing shapes may be used to achieve a good coupling to the ground, preferably with a directionality in space.

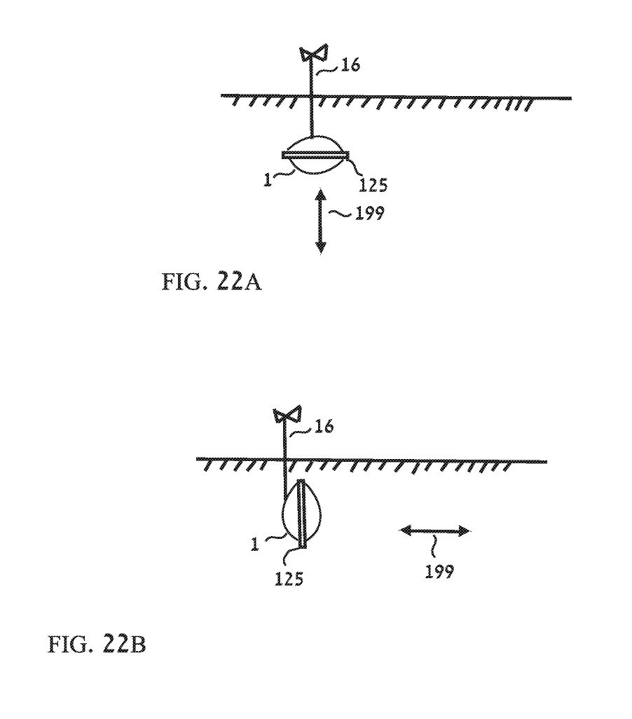

FIGS. 22A and 22B illustrate the use of the unit's directionality (sail) to adapt to various types of waves.

The unit 1 in FIG. 22A is so installed as to detect vertical waves as indicated with the direction 199.

The sail 125 (a ring circumferent to the unit 1) proffers a larger area normal to the directionality 199, to increase the unit's sensitivity in that direction.

If horizontal acoustic waves are expected, then the unit 1 is installed as illustrated in FIG. 22B, where the unit 1 is adapted to waves having directionality 199 as illustrated.

### 4. Integrated, Sealed, Shielded, Corrosion Protected, Stand Alone Unit

Preferably the novel device is an Integrated, sealed, stand alone sensor with electronic circuit, digital processor, transmitter and battery.

The units in FIGS. 4 and 5 illustrate embodiments of a device having a unique combination of integrated, sealed, stand alone geophone with a transmitter, electronic circuit, digital processor and battery in a self powered, long life unit. The Re-transmitter, sensor unit and local sensor/base station unit may have this structure.

The unit preferably contains multiple inputs from acoustic, seismic, temperature, humidity, radioactivity and other sensing inputs. Processing includes amplification, filtering, digitizing, digital processing and storage. The results are transmitted via wires or wireless.

Long life can be achieved, up to 20 years. The battery can be recharged via sun energy or external mobile source/charger. A Rechargeable battery may be used, with an external source or charger.

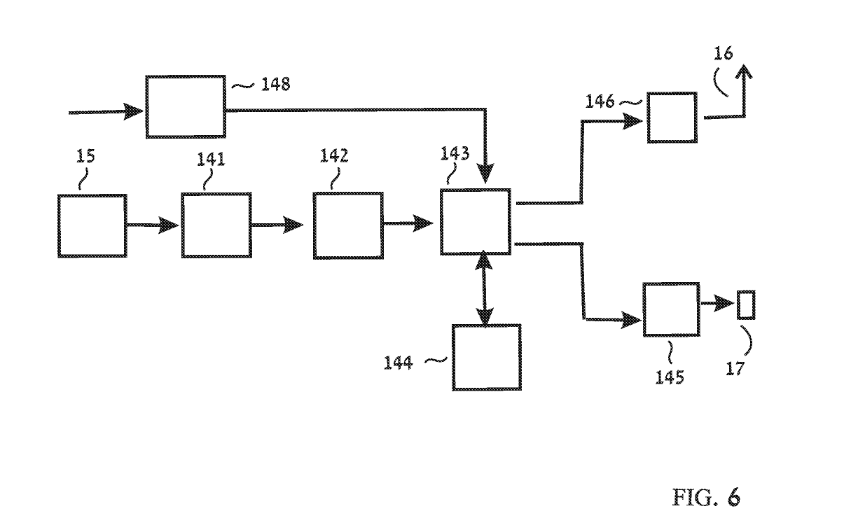

FIG. 6 details the functional block diagram of the acoustic sensor unit 1. This may be also used for the sensor part of a base station 2.

The block diagram may pertain to the devices illustrated in FIGS. 4 and 5.

Signals from the sensor 15 are transferred to an analog signal processing unit 141. The signals are further processed in filtering unit 142, then transferred to the digital signal processing and decision 143 with digital memory unit 144.

If an event occurred, it may be reported through a wire/fiber optics transmitter 145 with connector 17, and/or via an RF transmitter 146 with the antenna 16.

The analog to digital converter (ADC) 148 receives signals from the various sensors and the cathodic protection monitoring subsystem.

When using this option, the processing unit 141 also monitors changes in the cathodic protection voltage.

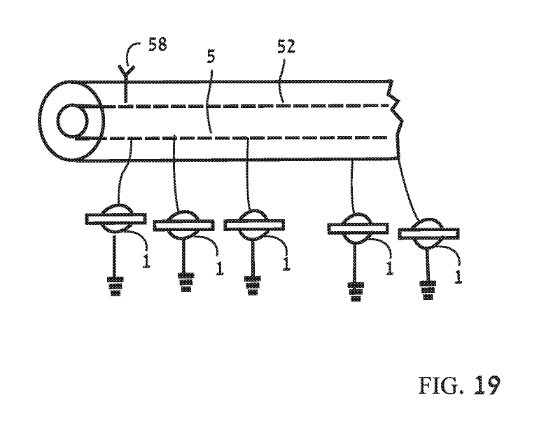

This aspect of the invention is further detailed elsewhere in the present disclosure, see for example the disclosure with reference to FIGS. 19,20,21.

An advantage of using geophones is they do not require a power source. Thus, geophones are well suitable for the sensor unit in the present invention, where a self-contained, low power consumption unit is achieved.

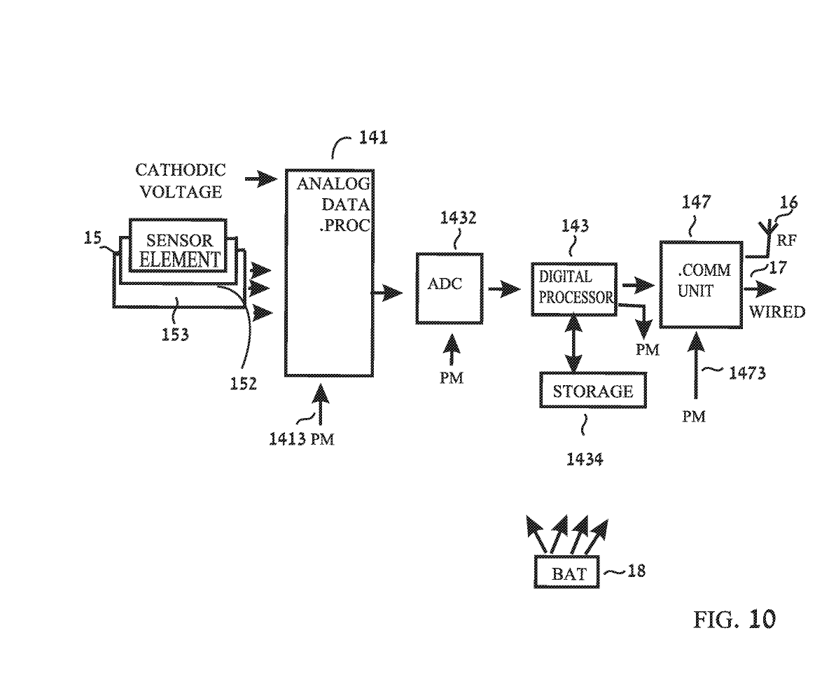

Another embodiment of a functional block diagram of the acoustic sensor unit 1 is illustrated in FIG. 10.

5. Using Measurements of the Cathodic Voltage Changes to Detect Offenders to, or to Protect from Faults in, Oil, Gas or Other Pipes

The system allows quick detection of pipe insulation breakage by offenders to, or protection faults in, oil, gas or other pipes.

A distributed system as illustrated may be used for quick detection of offenders of oil, gas or other pipes, or of underground high voltage cables, by monitoring the protective cathodic voltage and detecting quick changes in the voltage. A high dV/dt value between the pipe and the ground indicates a quick touch on metal of pipe, such as during drilling, causing damage or tap connection due to drop in local, pipe to ground insulation value.

Such activities result in a change in ground potential relative to pipe.

When measuring ground voltage relative to pipe—ground potential may change because of electrical resistance change from the pipe to the ground.

This system can also be used for insulated fences or underground shielded cables.

The present system measures the potential of ground relative to any isolated conductive constructions, or between two sensing electrodes.

The pipe is almost an ideal conductor. If ground to pipe difference is lower than given by external power supply (usually −0.9V on the pipe referred to ground), then the insulation is damaged or penetrated.

In a preferred embodiment, each 100 meter or several times 100 m, a unit 1 measures the cathodic voltage, then the results are used to evaluate damage to the insulation or an attack on the pipe.

The electric fields in the ground, in the vicinity of an underground high voltage cable, may be measured to detect problems there.

An isolated cable may be extended from a sensor, for example 1 meter to 10 meters, with a sensing plate at the end of the cable. The plate may simply comprise a conductor body making contact with the ground. The voltage difference will indicate leakage from the cable, and the cable temperature can indicate local overloading, or other destructive process in the nearest area.

The sensing unit may also include acoustic sensors, since a short circuit may also cause higher-frequency noise. For underground high voltage cable sensing, the preferred type of communication is through underground optical fiber for safety reasons. More distant sensors, for digging detection can use copper wires.

The system may display the location of damage or unauthorized access to the protected pipe or cable. This may be especially important for long cables, or where the cable or pipe passes within a city limits, where access may be difficult and expensive.

### Method for Detecting Offenders of Oil, Gas or Other Pipes

1) The above Methods for detecting intrusion and locating an intruder may be advantageously used to detect offenders of oil, gas or other pipes, by monitoring the protective cathodic voltage and detecting quick changes in the voltage.

2) These pipes and underground high voltage cables may be protected by processing data from the various sensors in the system.

3) The undesired activities may combine cathodic voltage changes with other noises which are detected; the path of intruders may be monitored to present a detailed picture of such activities, allowing to take necessary measures.

**End of method**

### Cathodic Protection Monitoring and Alarm System

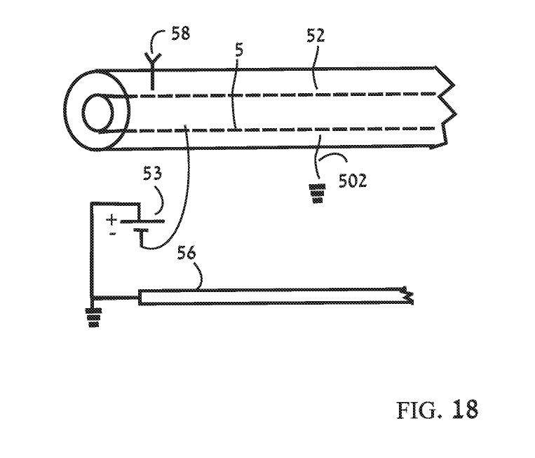

FIG. 18 details cathodic protection of a pipe or metallic construction to be protected 5, which preferably also includes an insulation 52, and a power supply 53 for cathodic protection, connected to an electrical ground or anode structure 56 (disposable, corroded over time). The ground is not one point, but a distributed structure, maybe a pipe.

It is important to measure the cathodic voltage along the pipe 5, to ensure the cathodic protection is still active. For that purpose, the pipe 5 may include a plurality of test points 58, for cathodic voltage measurement.

An unlicensed connection to the pipe 5 may appear as a short 502 to the ground; it changes the electric potential of the ground nearby, which may affect the cathodic voltage at that location (the voltage between the pipe 5 and the local ground).

It is a tedious, time-consuming process to measure the cathodic voltage for a long pipe, which may span hundreds or thousands of kilometer. Sometimes, there is no easy access to the pipe for such manual measurements.

### Method for Monitoring the Cathodic Voltage

An embodiment of a method according to the present invention comprises:

1) the present system is laid along the pipe 5, as illustrated for example in FIG. 3.

2) the pipe 5 (or test points thereon) are connected to nearby sensor units 1. The sensor units may include an analog input for this purpose, possibly with an analog to digital converter for measuring digitally the cathodic voltage, for example see ADC 148 in FIG. 6.

Each pipe has its own power supply, which applies a negative potential to the pipe 5 to be protected, relative to ground.

The pipe 5 is insulated from the ground.

3) The cathodic voltage is monitored in the system, together with the other variables being measured.

4) If a sudden change in the cathodic voltage is detected, an alarm may be issued. The event may relate to one or several adjacent sensors. Such a sudden change may indicate a voltage failure, a damage to the pipe or an unauthorized connection relating to theft of oil, for example. The location of the problem may be clearly indicated by the system.

5) Slow changes in the cathodic voltage may be caused by changes in the voltage of the power supply 53 itself. The system will ignore such changes. Preferably, the system will also measure the voltage of the power supply itself and will compare it with the cathodic voltage of the pipe.

**End of method**

Usually, there are several pipes in parallel, each with its own power supply and cathodic voltage protection.

Thus, a method is disclosed for detecting unauthorized access to oil, gas or other pipes, by monitoring the protective cathodic voltage and detecting changes in the voltage which are indicative of a technical failure or a deliberate attack on the pipe.

The cathodic voltage at a specific location is the voltage measured between the pipe and the ground at that location. A sensor unit as detailed elsewhere in the present disclosure may be used for that purpose.

In one embodiment, the voltage is measured by connecting a voltage measuring unit (the two inputs of the measuring unit) to the pipe and to the ground at that location.

In another embodiment, the connection to the ground is through the conductive body of the sensor unit, or using an electrode buried in the ground.

In the present system, the cathodic voltage is measured at a plurality of locations along the pipe, and changes in the voltage are reported to a center, together with the location where the voltage change has occurred.

This allows to take corrective or preventive actions, as the need be. Maintenance personnel may be dispatched to the problematic location, to repair what is required. Alternatively, security people may be dispatched to protect the pipe against an attack thereto.

In one embodiment, the detected change in the voltage comprises detecting a sudden change in the cathodic voltage.

Such a sudden change in voltage may be measured as a high value of dV/dt, which is indicative of an attack on the pipe, such as a touch on a metal of the pipe.

It is possible that the high value of dV/dt is caused by electrical current flowing from the pipe to ground.

The above sudden change in voltage is preferably measured at a plurality of locations along the pipe using the system disclosed in the present invention, and changes in the voltage are reported to a center, together with the location where the voltage change has occurred.

In yet another embodiment of the invention, the detected change in the voltage comprises detecting a drop in voltage for a prolonged time period. Such changes may occur at a slow rate—the voltage very slowly decreases. Such a drop in voltage for a prolonged time period may be indicative of a damage to the pipes's insulation.

In a preferred embodiment, the drop in voltage for a prolonged time period is measured at a plurality of locations along the pipe, and changes in the voltage are reported to a center, together with the location where the voltage change has occurred.

In yet another embodiment of the invention, the detected change in the voltage comprises detecting a reversal in polarity of the cathodic voltage.

Preferably, the polarity reversal is measured at a plurality of locations along the pipe, and changes in the voltage are reported to a center, together with the location where the voltage change has occurred.

In a preferred embodiment, the above methods may be implemented in a controller unit in each sensor unit. The software may check for each of the voltage changes to be monitored: a sudden change in voltage, a prolonged drop in voltage, a voltage polarity reversal.

FIG. 19 details a distributed measurement of the cathodic voltage. Test points from the pipe 5 are connected to the Cathodic voltage input of sensors 1. Sensors 1 are also connected to the local ground, thus measuring the voltage between the pipe 5 and the ground.

The pipe 5 being metallic, the potential is basically fixed along it.

The local potential of the ground, however, may change if there are problems. Thus, by measuring the local voltage between the pipe 5 and ground using sensor units 1, variations in the cathodic voltage relative to ground are monitored. For example, when an intruder touches the pipe 5, the local potential may change.

Such changes are detected and monitored at a higher level. Moreover, often such activities also involve heavy equipment, which makes noise and creates vibrations. Such effects may also be detected with the units 1.

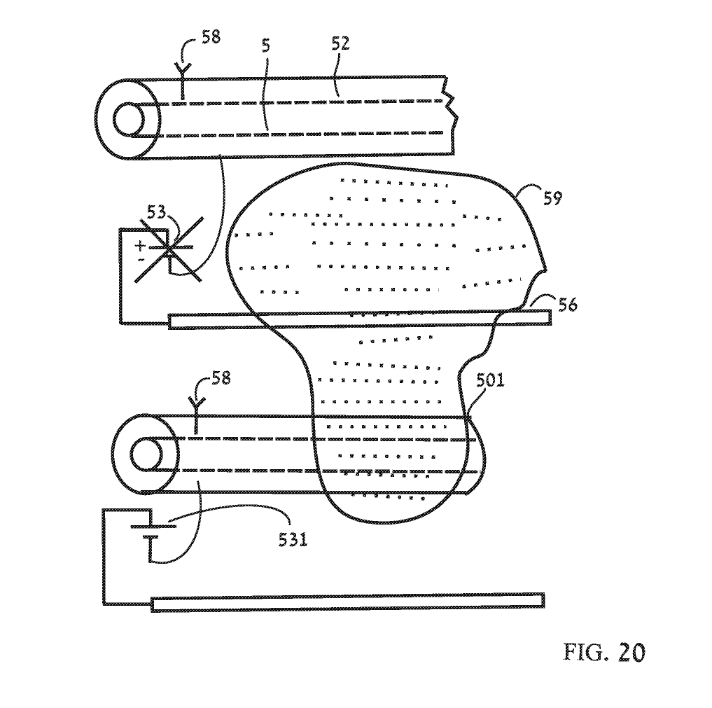

FIG. 20 details a failure mechanism of the cathodic protection:

a first pipe 5 may be short circuited to ground or the power supply 53 for cathodic protection may be damaged, thus creating an earth volume having positive ground potential 59.

This volume of positive potential may damage another pipe 501 in that area.

Thus, if a PS shorted, damaged—then around the second pole a positive ground potential may occur, because of second PS field. Then a second pipe is positive, then excess positive voltage. If the insulation is damaged, then in several weeks there may be a hole in the pipeline.

Therefore, it may be important to measure the voltage of each pipe, every 800-1000 meters, and report in real time—between checks if reverse voltage was detected. Such a voltage may indicate a possible damage occurring to a pipe.

There is no need to inform the operator on the constant voltage at a high rate—a sensor to measure the voltage once per hour will be sufficient.

A sudden change in the cathodic voltage may be indicative of a theft attempt. This embodiment requires a very fast response and message generation, to inform the pipe service personnel.

The sensor unit 1 may also include thermometer means for measuring the temperature in the ground. Using an adequate sensor such as a thermistor, temperature values can be converted to electrical signals, to be processed in the sensor unit 1 like any other sensors data.

A temperature differential may be indicative of an oil spill out of the pipe. A small leakage may be difficult to detect using direct methods, but there may be a practical solution—the leak may cause a temperature difference of about several degrees, relative to ambient ground. This difference may be indicative of a leakage. Oil may be heated, and if there is a leakage, then it heats the ambient.

The sensor unit 1 may also include a humidity sensor, whose output (an electrical signal) may be processed as well for protection purposes.

Furthermore, the acoustic sensor data may be used to detect leakages in the pipe or local movements of the ground. An oil spill or other events may cause such movements, which may be accompanied by acoustic signals which are then detected by the geophone or other acoustic sensor.

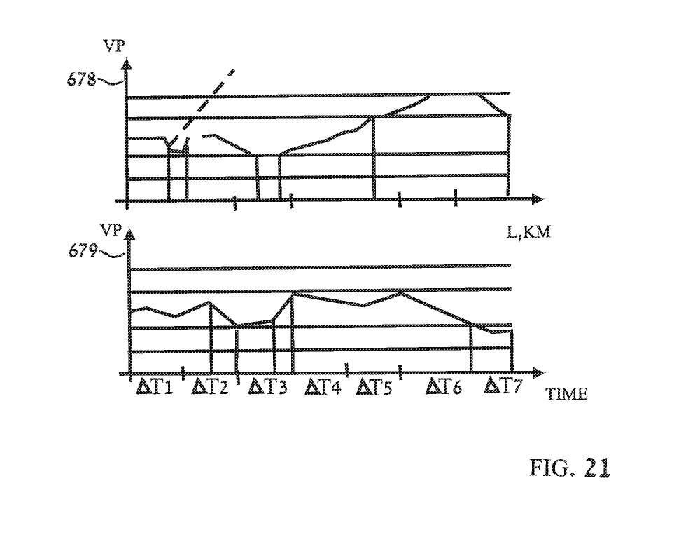

FIG. 21 illustrates signals in a system for cathodic voltage monitoring, a two-dimensional display:

signal vs. location 678
signal vs. time 679.

These are the signals input to the analog to digital converter (ADC) 148 for cathodic protection subsystem see FIG. 6.

### 6. A Sophisticated Algorithm for Processing Sensors Data in a Four Dimensional Space Including Location and Time

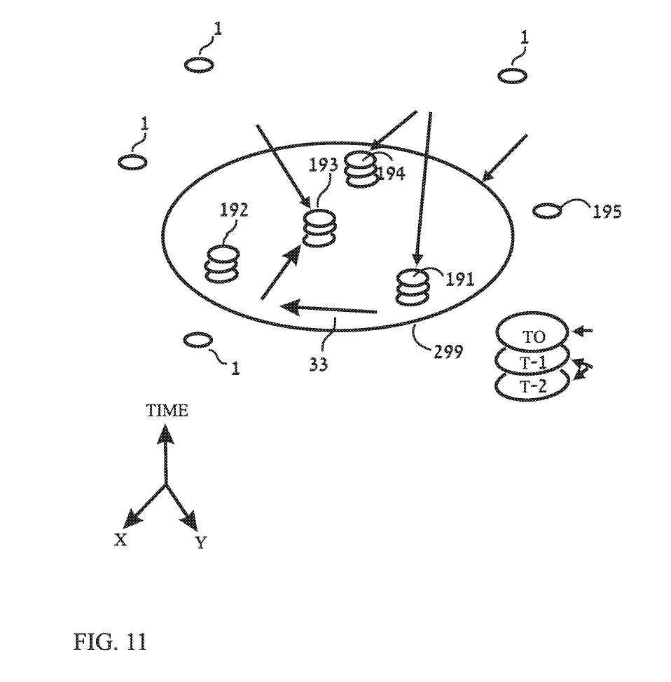

FIG. 11 illustrates an algorithm for detecting an intruder's path in a four-dimensional (space and time) space. The log of a sequence of sensor's activation reports includes:

sensor activated at time T−2, 191
sensor activated at time T−1, 192
sensor activated at time T−0 (now), 193.

From this information, the intruder's estimated path 33 may be computed.

The system may include other sensors 1, 194, 195, which were not activated in this case.

The processed sensors may belong in a physical/actual radius of detection 299, neighbors by definition.

### Method of Data Processing

1) The path evaluation may be done at level 3, in the LC

2) The LC receives reports of one sensor active, then checks adjacent sensors status, then checks over time for the same activated sensor—past history, to detect an extensive activity in this specific location, then checks adjacent sensors, that belong to a predefined logical group—simultaneous detection in 2-4 sensors from group of 5-6, usually will indicate human activity or big animal presence.

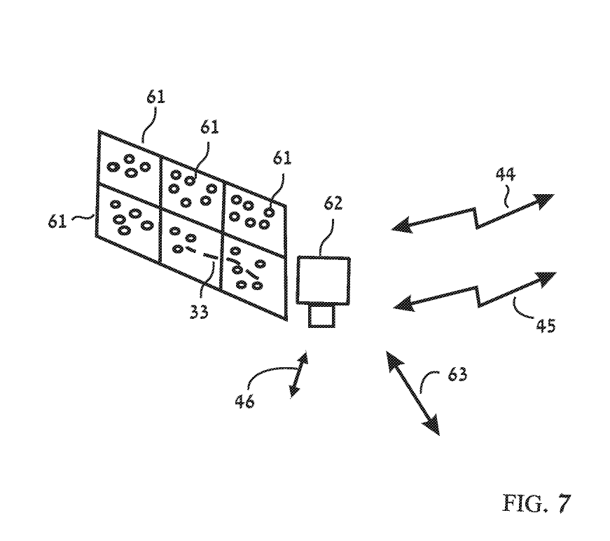

Human activity will usually differ from animal's by the amount of quick actions on a single location, combined with slow motion over space. Sequential activation indicates a movement from one location to the next (this is the case illustrated in FIG. 7).

3) Performing a four-dimensional analysis, 3 dimensions in space, plus time, for each sensor and for every event, allows the system to filter out many possible false alarms.

Typical false alarm can be caused by small animal activity near single sensor, but the system will recognize it as quite long activity in one location that is not looks like human.

Another obvious false alarm case is rain, when a big group of sensors signaling for long time. The system will ignore it in most cases.

Another natural phenomena that will activate very big group of sensors for short period, is earthquake. The system will ignore it in all cases.

The system usually detects real local activity and movement from one sensors group to another, with a very low ratio of false alarm, due to sophisticated methods, like those described above.

4) The system uses algorithms that are similar to human vision. A big amount of sensors form a wide picture, that can be analyzed and processed as a decision matrix over space, or time domain.

5) Real activity is detected with reference to a specific local pattern, in which adjacent sensors are activated, within a physical radius i.e. 100-200 meters—these are neighbors by definition, and forms a logical group to be compared with them.

If only one sensor was used or activated, then it checks history of sensors in that area.

6) From this analysis, a possible estimated path 33 emerges.

7) When different types of sensors are used, then multi-channel algorithms are activated as well. A typical example, and 99% indicator of offender on specific location of a pipe, is a simultaneous presence of cathodic voltage quick drop, and local seismic noise in radius of 100-200 meters. Prior to this will be detected signs of movement and approaching to the intrusion area by people or cars, that may be detected by an adjacent sensors array.

**End of method**

### Method for Detecting an Intruder's Path

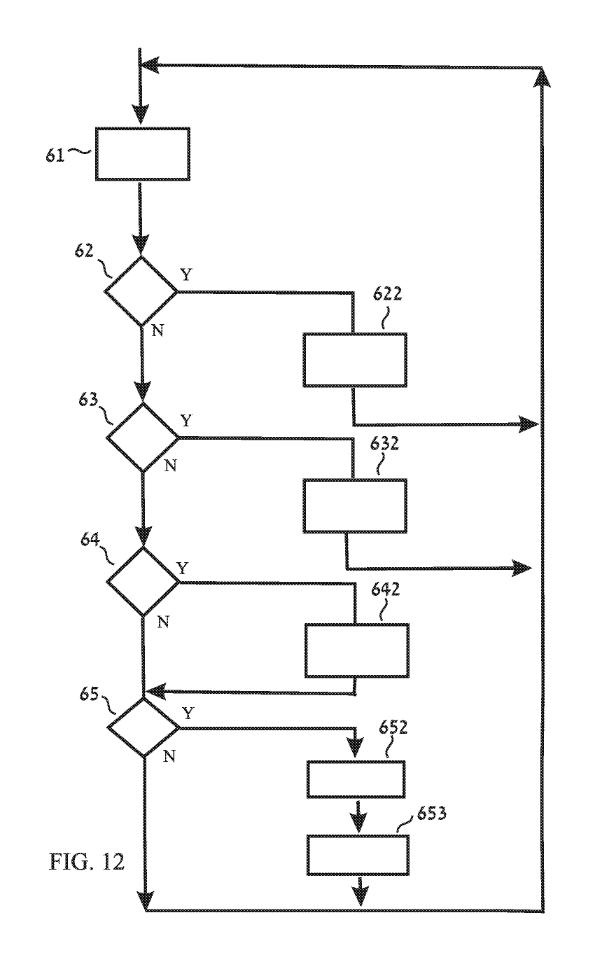

FIG. 12 details a flow chart of an algorithm for detecting an intruder's path in the four-dimensional space, including:

1) receive signals from a plurality of sensors (poll sensors) 61
2) many sensors activated simultaneously? 62 if yes goto 622
3) natural phenomena, ignore 622
4) a single sensor is activated? 63 if yes goto 632
5) ignore or increase threshold 632
6) a few sensors activated simultaneously? 64 if yes goto 642
7) compute precise location of event 642
8) sequential sensors activation? 65 if yes goto 652
9) estimate intruder's path 652
10) activate alarm, display path 653
**End of method**

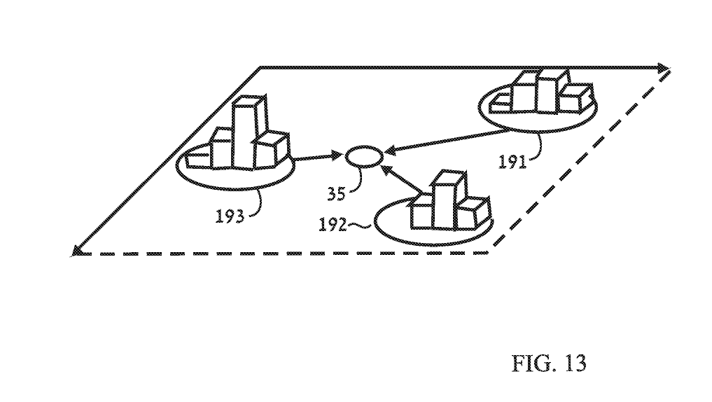

FIG. 13 details an example of computing the precise location from the simultaneous activation of several sensors 191, 192, 193.

For each sensor, there is a history of received signal amplitude vs. time. Using this information, an intruder's precise location estimate 35 can be computed.

### Method of Computing an Intruder's Precise Location

1) The method is performed in the LC

2) If several sensors activated simultaneously, each sensor may send a report every few seconds, possibly it may be divided into several time divisions.

The reports relate to the largest, strongest event in that time.

The reports may include digitized, maximal amplitude over that time.

The reports may include steps count per each time period.

The reports may include average signal level per each time period.

3) In a preferred embodiment, the transmit protocol may save in data to send, by sending 16 bits, 4 bits each level one each event. The number of bits is presented as an example. Other modes, with other parameters, are possible.

This reduces the volume of reports, and again gives the full picture.

Thus, the 16 sec time interval is divided into 4 parts of 4 seconds ea., or 2 parts of 8 seconds, or 8 parts of 2 seconds, etc.

It then sends for each 4 sec-4 bits of signals corresponding data.

In this example—an event description coded in 4 bits.

The data from a sensors array is used to estimate the event location.

4) In each sensor unit, the operator can program the threshold—what event will be reported to a higher level, and the signal pattern.

The threshold may be set according to ambient conditions.

The detection threshold, in digital form, may be set in the digital processor in the detector/sensor unit. Moreover, the operator can also define/set the analog gain, bandwidth, steps counter and/or other parameters.

**End of method**

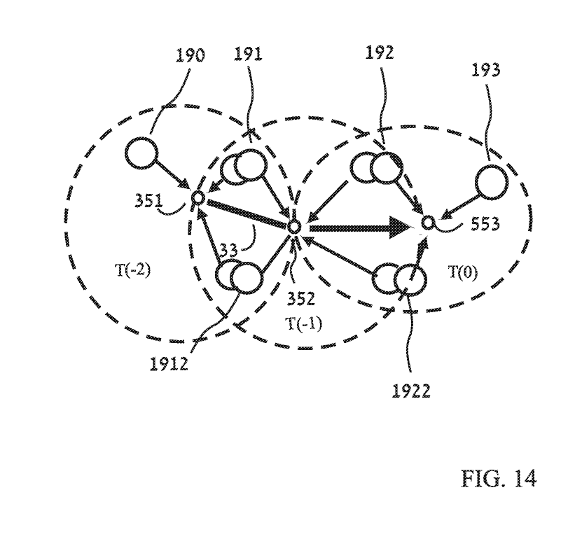

FIG. 14 details an example of the sequential activation of a plurality of sensors:

sensors activated at time T−2, 190, 191, 1912
sensor activated at time T−1, 191, 1912, 192, 1922
sensor activated at time T−0 (now), 192, 1922, 193.

From these data, intruder's precise locations estimates 351, 352, 353 can be computed.

The intruder's estimated path 33 can next be computed, as an interpolation or best estimate between the above points.

Intruder detection method. An intruder moves over group of sensors. In FIG. 14, circles denote sensors; An overlap or shadow indicate the same sensor, over time. Thus, for example, the t−1 event is detected in 4 sensors. The t0 event is detected in 3 sensors.

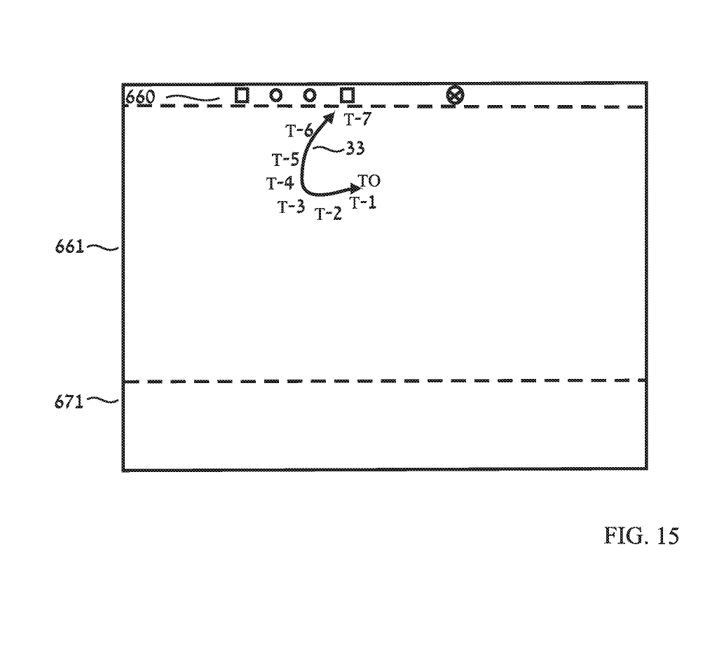

FIG. 15 illustrates an example of a graphic reporting display and log file for a walk-in intruder, including:

1) a graphic (map) display 661 with an example of an intruder's estimated path 33, at times T−7, T−6, T−5, T−4, T−3, T−2, T−1, T−0 (now).
2) Log (data) display 671
3) control tools 660

In this display method, the path of walking is presented on an operator display with example of intrusion at time t0, t−1, t−2, t−3 . . . t−7, and where the intruder's path is superimposed on a map of the protected area.

Using control tools in software, the operator can define how much points to display from the log file.

Too little information or too much may obscure the actual events taking place.

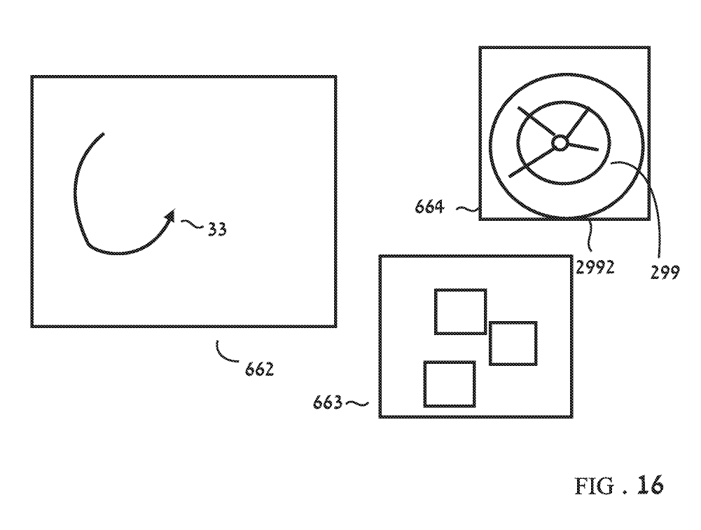

FIG. 16 details an example of distance evaluation from sensor signal strength data. Shown are the physical/actual radius of detection 299, with neighbors by definition, and the logical radius 2992 for the group of sensors.

There are several map views 662, 663, 664—these are details of the display in FIG. 15.

In this example, distances from sensors are computed from amplitudes measured at three sensors.

Also shown is an example of an intruder's path.

Physical radius—according to media behavior.

Logical radius—according to location of sensors, layout of system/network Every time, we analyze groups of sensors and compare data on a time axis (correlate events over time).

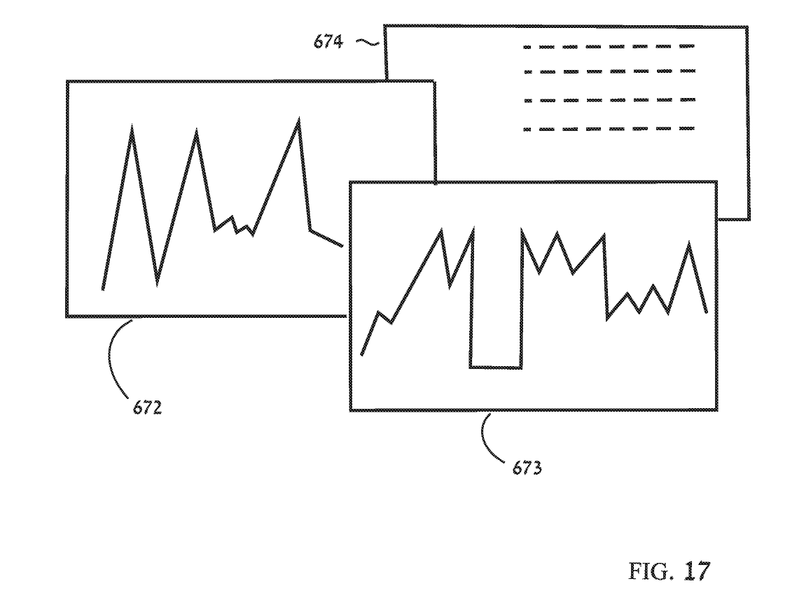

FIG. 17 details an example of a display of historical data for a single sensor activation, in both graphic and tabular form over time, including:

history of signal data 672, for sensor No. 4 at base No. 0,
history of signal data 673, for sensor No. 4 at base No. 0 at a previous date, sensors activation log 674.

Using software controls, the user may select which sensor or sensors to review, for any time interval as desired. This display method may be used to investigate present or past events.

7. Detect Leakage from Pipe Using Multiple Channels/Inputs

Detect leakage from pipe using multiple channels/inputs: A Multi-frequency sensor unit reduces false alarms while providing reliable detection of liquid leakage from the pipe, using a small, low cost sensor unit.

Detect leakage from pipe using multiple channels/inputs. Multi-frequency sensor unit reduces false alarms while providing reliable detection of liquid leakage from the pipe, using a small, low cost sensor unit.

A pipe in the ground is conduit for a liquid under pressure. A leakage's effects may include seismic noises, as the liquid enters into ground, moves stones and strata therein, blocks water paths, etc. Such noises are in the 0.1-300 Hz frequency range. Most of energy is at about 1-70 Hz as the ground moves.

Accordingly, the present sensor unit 1 includes acoustic and/or seismic sensors up to 200 Hz, to detect seismic noise.

Another effect of leakage is cavitation noise, generated when a liquid exits from high pressure area to lower pressure area. This cause strong and chaotic turbulences of liquid. When this happens, small bubbles of gas are popping out in the pressure border zone. The popping bubbles energy is absorbed by the liquid and the pipe walls. The pipe vibrates at a high frequency, and transfers part of the energy to the ground. The same may happen in gas pipe leakage, when a typical “whistle” can be heard.

The Frequency range of such noise is sonic and ultrasonic, usually within 100 Hz to 30 kHz, when most of the energy is present in the 200 Hz-2 kHz range.

The pipe transmits those vibrations to the ground. At these higher frequencies, the pipe is a better sound conductor than the ground, which acts like a low pass filter.

This energy can be detected only near the pipe so the preferred location of such a sensor is every 70-150 meter, 0.5 to 1 meter distance from the pipe. A Closer location to the pipe may induce some distant noises, that propagates through the pipe's walls.

In a typical solution, there will be use of acoustic and seismic sensors. The electronic circuitry will form at least two frequency paths: one will filter out signals under 200 Hz, retain above 200 Hz—to delete seismic noise. This will detect “bubbles whistle”, high frequency sound, above 200 Hz.

Another path will filter out signals above 100 Hz, and will detect only seismic noises caused by movement of the soil, when liquid leakage will displace volumes around the pipe.

If both acoustic AND seismic signals are detected—then this is a reliable indicator of leakage from the pipe. It is most unusual to have both signals for other occurrence.

Moreover, the system checks the noises for a significant time period, for example for at least few seconds, to eliminate short sporadic noises such as birds which can whistle, but only for a short time. The valid time for alarm may be adjusted and adapted to expected events, the type of ground, presence of birds, etc.

This dual sensor unit reduces false alarms, and reliably detects real leakages. The system may further check for a local change in ground temperature which is caused by oil spills. This is another possible input to the system.

Multiple inputs: Geophones array including several geophones.

Natural resonant frequency of geophone is usually a disadvantage, due to inaccuracy of phase and other measurements. Various methods like dumping techniques are used to make flat response over the frequency range.

This invention make use of this physical effect to form an array consist of several geophones with different resonant frequencies.

Those resonant frequency may be for example 4.5, 10, 14, 20, 28, 35, 50, 60, 75, 100 Hz. When no dumping is used, the sensitivity of the geophone may be about 2-3 times higher in the center of its natural resonance frequency. This will give better signal to noise ratio and higher selectivity to this specific frequency, without the need to spent energy on filtering, or signal processing.

Advantage of geophone: it does not consume electric power. Thus, a sensor unit 1 can use an array of 4-5 geophones for example, and achieve seismic frequency separation with lower energy consumption.

A decade of geophones may be used, each geophone has natural resonance frequency where it is more sensitive. Preferably the geophone uses no damping resistor. The geophones array performs a kind of spectral analysis of the signals, at a low power consumption. Performing spectral analysis on a Digital Signal Processor (DSP) would consume more power.

Rather than one sensor, the unit may use a plurality of sensors, for example including temperature, humidity, etc.

The sensor means may include acoustic, seismic, temperature, humidity and/or radioactivity sensors.

The sensor means may include geophones, microphones, accelerometers, magnetometers, temperature, humidity, radiation and/or other sensing elements.

A plurality of geophones may be used, each tuned to a different frequency. Preferably, the damping is reduced (for example by removing or increasing the resistivity of the damping resistor). This results in increased sensitivity, at the expense of narrower bandwidth. The latter effect may be corrected by using a bank of geophones.

To detect leakage from pipe using multiple channels/inputs, other sensors may include a Multi-frequency sensor unit.

Various sensors may be used to improve sensitivity and reliability of the device, and to reduce the false alarm rate.

### 8. Communication Protocol, Low Power—Economic on Use of Battery Power

A novel method and system may be used to achieve a low power consumption, efficient communications protocol. Preferably, there is a bi-directional link between sensors and a base station. Reports are sent from each sensor to the base and are acknowledged. Errors are corrected, sensors' status is maintained at the base to indicate sensor's performance.

### Communication Protocol and Method

a. In a preferred embodiment, the communication protocol may use a FSK or GFSK modulation of the radio-frequency carrier. Other modulation types may be used, such as BPSK, QPSK, OFDM, etc. The modulation type is preferably adapted to the type of medium used (wired or wireless, metal wire or fiber optics, etc.), the noise level in the medium, etc.
b. Sensors data size and structure are constant, and consist of several fields. A constant size field is assigned to each of the relevant parameters of the communication message.
c. The sensors message may include:
   1) a 8 to 16 bits long preamble of a start sequence, for example a binary 1010 . . . binary sequence
   2) a sync sequence of for example 8 bits of a 11001100 sequence,
   3) a sensor's unique ID number of for example 8 to 16 bits
   4) several bits of sensor's internal clock counter
   5) several bits indicating the message type
   6) data, for example 16 bits of data
   7) CRC (for Cyclic Redundancy Check purposes), for example 8 to 16 bits
d. Sensor's transmission is usually followed by an immediate reply from the base station, in a constant structure and data size.
e. The base station checks the data validity, using a special 8-16 bit CRC field in the received message; if the message is damaged, the base station immediately sends back a request to repeat the message. Up to 4 sequent requests are allowed, and if no valid data received, then this specific sensor is marked in the base station memory as Fault type 1—communication error.
f. The protocol allows to a specific sensor to miss up to 15 sessions of transmission. This number may be predefined remotely and is used to save transmission energy, if no event happened. If this number is exceeded, then the sensor is marked in the base station memory as Fault type 2—complete malfunction.
g. The protocol may use the sensor's internal clock bits to check its synchronization to a general system clock. If the allowed value is exceeded, then the sensor is marked in the base station as Fault type 3—clock shift, (aging and temperature factor shift of quartz, due to very long life of each sensor). This data can be used for remote compensation. In the same way, the base station receives sensors battery status, and if the voltage drops over the years under a predefined value, then the sensor is marked as Fault type 4—weak battery.
h. If the sensors message is OK, the base station sends back several fields of data. This data may include:
   1) the sending base ID
   2) recipient sensor's ID
   3) message type
   4) message data. The Message data may include the gain, sensitivity level, sampling rate, transmission duty cycle and next session frequency, and other parameters used by the system.
i. One of the most important fields in every back message, is the dynamically changing 8 bits of general system clock, to synchronize sensors clock shift, that is used for next transmission time calculation
k. All messages may have a constant length, thus not all data can be sent at once. A polling queue technique may be used to send back to the sensor, first the highest priority data, then the second priority data on the next session, and so on.
l. Sensors data may be transmitted on a time multiplex scheme to a base: A report from Sensor #1, then Sensor #2, Sensor #3, etc.;
   wherein each sensor only sends a report if a significant event was detected, or a keep-alive periodic report.
m. The base station receives all the sensors data, processes them and transmits a report to a center or a base higher in the hierarchy. The upstream of sensors data from base to base can be done in a similar multiplexed way. In large systems, with many sensors and frequent transmissions, duplex method on several RF channels can be used to increase the throughput and decrease the response times.
   **End of method**

### Wireless Communications Protocol/Method

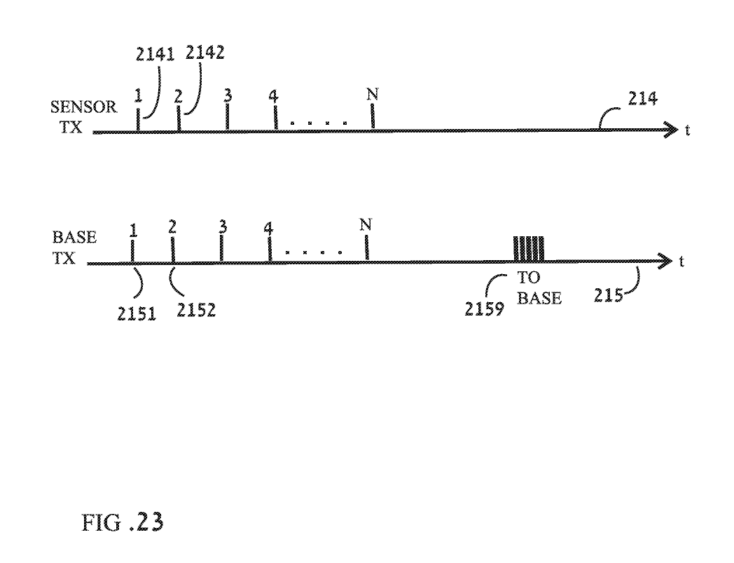

1) FIG. 23 illustrates a wireless communications protocol.

Sensors data 214 can be transmitted on a time multiplex scheme as illustrated: A report from Sensor #1, then Sensor #2, etc.

Each sensor only sends a report if a significant event was detected, or a keep-alive report. A keep-alive report may be only send at a lower rate as predefined in the communication protocol.

2) The base station receives all the sensors data, processes them and transmits a report 2159 to a center or a base higher in the hierarchy.

3) The base station may transmit commands to sensors 2151, 2152 where required, for example to change sensitivity, etc. Preferably a transmission to a sensor such as 2152 is made immediately following a reception from that sensor 2142; The sensor unit, after transmitting to, and possibly receiving from, the base, enters a low power consumption “sleep” mode.

**End of method**

### Wireless Communications Method at the Sensor Unit

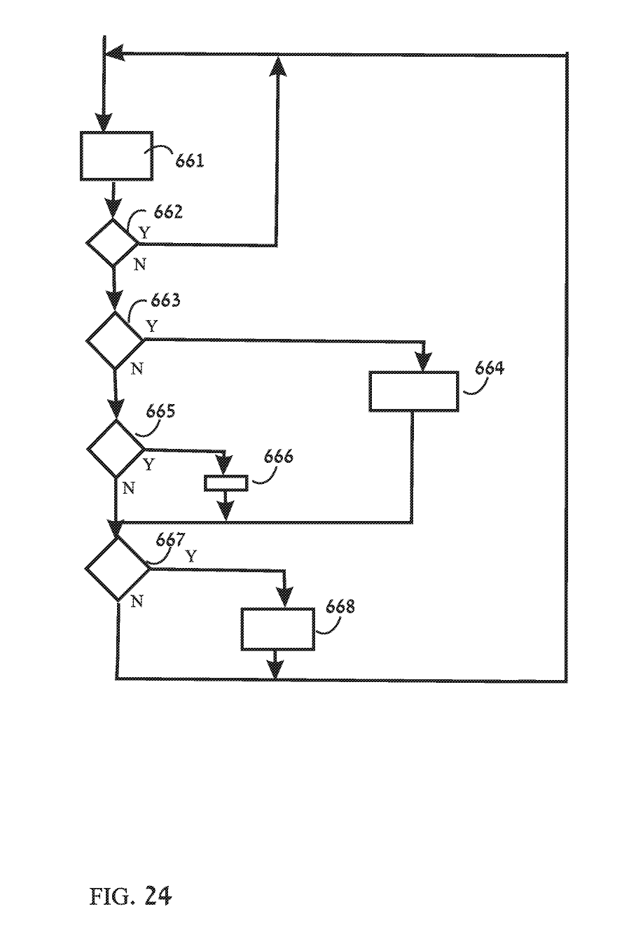

FIG. 24 details a wireless communications method at the sensor unit.

The method includes:

a. measure sensor(s) data 661
initial processing
store info
b. check: time to transmit? 662
if not, continue measuring sensor data
c. check: are there events to transmit? 663
d. if Yes, then transmit events 664
e. if no events to transmit, check:
time to stay alive message? 665
f. if time: transmit stay alive message 666
g. time to receive commands from base?
h. receive commands from base.
**End of method**

### Wireless Communications Method at the Base Unit

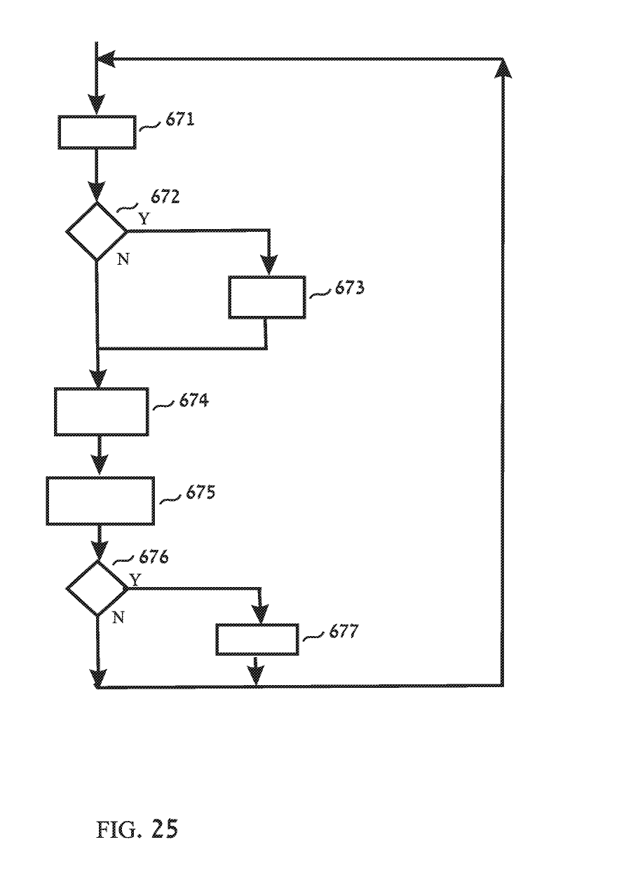

FIG. 25 details a wireless communications method at the base unit. The method includes:

a. measure sensor(s) data 671
initial processing
store info
b. check: time to receive from sensors? 672
c. receive sensor reports 673
d. check whether all sensors are active 674
e. send report to center 675
f. check: time to transmit to sensors? 676
g. send commands to sensors 677
**End of method**

FIG. 7 illustrates a display and control station using a graphic human interface. Reports of events of sensors activation may be received through Ethernet links 46 or other links from a remote LC, such as a radio datalink 44 or a Wimax link 45.

The system may be used for detecting cathodic voltage fluctuations and/or other sensors activation.

The system may include components of the Supervisory Control and Data Acquisition system (SCADA).

The information is preferably presented on graphic display screens 61. One or more such screens 61 may be used.

For example, a possible intruder's path 33 may be displayed.

The data may be stored and processed in a computer/server 62 with graphic human interface/controls 63.

Various means of graphic interface unit GUI, to a SCADA system may be implemented.

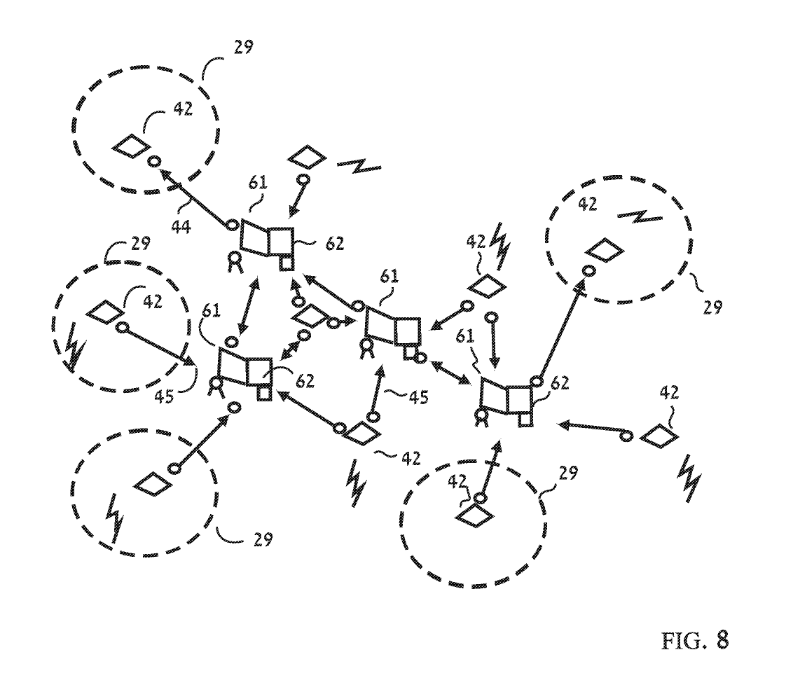

FIG. 8 illustrates a distributed system with multiple display and control stations. The system supervises a plurality of cells 29, each cell with sensors, a base station and connected to the network. Each sector may include several cells and may span an area of more than about 10 square kilometers in size.

Each display and control station may include graphic display screens 61 and a computer/server 62.

The system may also include level 3 analysis Local Computers (LC) 42, preferably one LC per sector.

An LC may process data from a remote sector, data may be re-directed according to workload in the system.

The above components may be connected in a Supervisory Control and Data Acquisition system (SCADA). In one embodiment, only monitoring of sensors data is performed. The system may include a measure of redundancy, with the same data being reported and displayed on several display means 61 (duplicate display).

In another embodiment, the operator can control the parameters of each sensor unit, such as its bandwidth and sensitivity. This may be useful where there are frequent false alarms, for example a sensor near a railway with false alarms issued each time a train passes by.

Thus, the system allows for duplicate monitoring and control, also from remote locations, of the entire network.

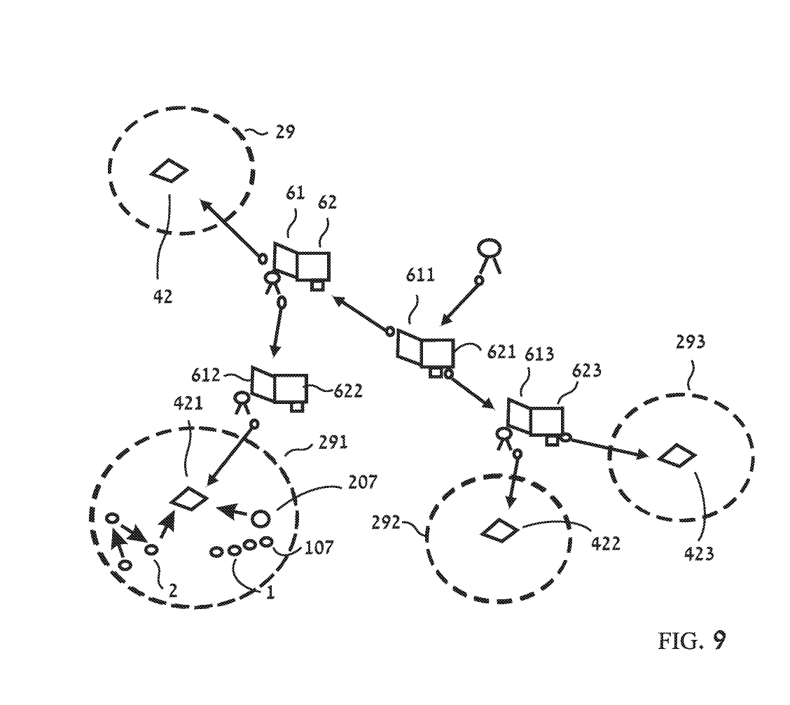

FIG. 9 details control paths for making changes in the system.

A user or operator may control the system, for example from the graphic display screen 611 (or any of the other screens 61, 612, 613). Commands are entered through the computer/server 621 (or any of the other units 62, 622, 623).

Such a command may refer, for example, to change the sensitivity of the sensor unit 107 in cell 291.

A message to that effect is transferred from server 611 to server 62, then to server 622, then to the level 3 analysis computer (LC) 421 in cell 291, then to the base unit 207 and finally to the sensor unit 107.

Benefit: an operator at a higher level may observe that a specific sensor is activated often, whereas other sensors are not. That specific sensor may be located near a source of interference or noise, such as a railway, etc.

The system allows control over any single sensor unit from a remote location. A specific sensor may be controlled from one of a plurality of control locations in the system.

Intelligent use of this feature allows to reduce false alarms and adapt the system to real life situations, while preserving readiness and effective detection of real threats.

FIG. 10 details another embodiment of the functional block diagram of the acoustic sensor unit 1, or the sensor part of a base station 2.

The block diagram may pertain to the devices illustrated in FIGS. 4 and 5.

Signals from a plurality of sensors 15, 152, 153 . . . are transferred to an analog signal processing unit 141. The signals may be further processed in a filtering unit (not shown).

Unit 141 and the other parts of the device may have a power management (PM) control input 1413, to disable the unit while not in use, by disconnecting it from electric power or significantly reducing its power consumption. Some devices may be induced into a “sleep” mode.

Thus, the various parts of the unit are activated in pulses, preferably low Duty Cycle pulses: short periods of measuring the sensors, interspersed with longer periods of wait/sleep/low power consumption.

then transferred to the digital signal processing and decision 143 with

During the short “active” time periods, the sensors signals are processed and stored in the digital memory unit 1434.

The analog to digital converter (ADC) 1432 receives signals from the various sensors and the local cathodic voltage from a pipe to be protected.

The unit further includes a digital processor 143 for processing samples of the measured sensors data, keep them in storage means 1434 and send the results to a higher level in the system hierarchy, using a communications unit 147 with wireless 16 and/or wired/cable means 17. If an event occurred, it may be reported through a wire/fiber optics transmitter 145 with connector 17, and/or via an RF transmitter 146 with the antenna 16.

The digital processor 143 further generates the Power Management (PM) signals for the rest of the system. There are controllers/microcomputers with such watchdog circuits built in; otherwise, a timer circuit may be used to generate the PM pulse train.

A battery 18 supplies power to the unit. An integrated, independent unit is thus achieved.

When using this option, the digital processor 143 also monitors changes in the cathodic protection voltage.

This aspect of the invention is further detailed elsewhere in the present disclosure, see for example the disclosure with reference to FIGS. 18-21.

The sensors may communicate with a base station or with each other. In the latter case, the sensors are cascaded so each will send its data to an adjacent sensor and so on.

Sensors communications may use CAN-BUS or RS485 or other multiple users wired protocols.

It will be recognized that the foregoing is but one example of an apparatus and method within the scope of the present invention, and that various modifications will occur to those skilled in the art upon reading the disclosure set forth hereinbefore.

What is claimed is:

1. A Wireless communications protocol and/or method comprising:
a. Sensors data size and structure are constant, and consist of several fields;
b. The sensors message include one or more of the following:
1) a 8 to 16 bits long preamble of a start sequence, for example a binary 1010 . . . binary sequence
2) a sync sequence of for example 8 bits of a 11001100 sequence
3) a sensor's unique ID number of for example 8 to 16 bits
4) several bits of sensor's internal clock counter
5) several bits indicating the message type
6) data, for example 16 bits of data, and/or
7) CRC (for Cyclic Redundancy Check purposes), for example 8 to 16 bits.

2. The Wireless communications protocol/method according to claim 1, wherein
c. Sensor's transmission is followed by an immediate reply from the base station, in a constant structure and data size.

3. The Wireless communications protocol/method according to claim 1, wherein
d. The base station checks the data validity, using a special 8-16 bit CRC field in the received message; if the message is damaged, the base station immediately sends back a request to repeat the message. Up to 4 sequent requests are allowed, and if no valid data received, then this specific sensor is marked in the base station memory as Fault type 1—communication error.

4. The Wireless communications protocol/method according to claim 1, wherein
e. The protocol allows to a specific sensor to miss up to 15 sessions of transmission, wherein this number may be predefined remotely and is used to save transmission energy, if no event happened; If this number is exceeded, then the sensor is marked in the base station memory as Fault type 2—complete malfunction.

5. The Wireless communications protocol/method according to claim 1, wherein
f. The protocol uses the sensor's internal clock bits to check its synchronization to a general system clock; If the allowed value is exceeded, then the sensor is marked in the base station as Fault type 3—clock shift, (aging and temperature factor shift of quartz, due to very long life of each sensor), This data can be used for remote compensation, and In the same way, the base station receives sensors battery status, and if the voltage drops over the years under a predefined value, then the sensor is marked as Fault type 4—weak battery.

6. The Wireless communications protocol/method according to claim 1, wherein
g. If the sensors message is OK, the base station sends back several fields of data, and This data includes one or more of the following:
1) the sending base ID
2) recipient sensor's ID
3) message type
4) message data.

7. The Wireless communications protocol/method according to claim 6, wherein the Message data includes the gain, sensitivity level, sampling rate, transmission duty cycle and next session frequency and/or other parameters used by the system.

8. The Wireless communications protocol/method according to claim 1, wherein
h. One of the most important fields in every back message, is the dynamically changing 8 bits of general system clock, to synchronize sensors clock shift, that is used for next transmission time calculation.

9. The Wireless communications protocol/method according to claim 1, wherein
i. All messages have a constant length, thus not all data can be sent at once, a polling queue technique is used to send back to the sensor, first the highest priority data, then the second priority data on the next session, and so on.

10. The Wireless communications protocol/method according to claim 1, wherein
j. Sensors data are transmitted on a time multiplex scheme to a base: A report from Sensor #1, then Sensor #2, Sensor #3, etc.;
wherein each sensor only sends a report if a significant event was detected, or a keep-alive periodic report.

11. The Wireless communications protocol/method according to claim 1, wherein
k. The base station receives all the sensors data, processes them and transmits a report to a center or a base higher in the hierarchy; The upstream of sensors data from base to base is done in a similar multiplexed way.

12. The Wireless communications protocol/method according to claim 1, wherein in large systems, with many sensors and frequent transmissions, duplex method on several RF channels are used to increase the throughput and decrease the response times.

13. The Wireless communications protocol/method according to claim 1, wherein the modulation type in the communication protocol is adapted to the type of medium used (wired or wireless, metal wire or fiber optics, etc.), and the noise level in the medium.

14. The Wireless communications protocol/method according to claim 1, wherein the modulation type in the communication protocol is FSK or GFSK.

15. The Wireless communications protocol/method according to claim 1, wherein Sensors data size and structure are constant, and consist of several fields; A constant size field is assigned to each of the relevant parameters of the communication message.

16. The Wireless communications protocol/method according to claim 1, wherein the base station transmits commands to sensors where required, for example to change sensitivity, bandwidth, etc.

17. The Wireless communications protocol/method according to claim 16, wherein the transmission from base to sensor is made immediately following a reception from that sensor.

18. The Wireless communications protocol/method according to claim 1, wherein the sensor units, after transmitting to, and possibly receiving from the base, enters a low power consumption “sleep” mode.

19. The Wireless communications protocol/method according to claim 1, wherein at least one of the Sensor's data are transmitted to an adjacent sensor rather than to a base.

20. The Wireless communications protocol/method according to claim 19, wherein a plurality of sensors each transmits its data to an adjacent sensor, to form a distributed, cascaded sensors link.
